(19) United States
(12) Patent Application Publication
(10) Pub. No.: US 2019/0088488 A1
(43) Pub. Date: Mar. 21, 2019

(54) METHOD FOR MANUFACTURING SEMICONDUCTOR DEVICE

(71) Applicant: NANYA TECHNOLOGY CORPORATION, New Taipei City (TW)

(72) Inventors: Hung-Yu CHI, New Taipei City (TW); Chien-An YU, Taoyuan City (TW); Yi-Fong LIN, New Taipei City (TW); Feng-Ling CHEN, Taoyuan City (TW)

(21) Appl. No.: 16/192,767

(22) Filed: Nov. 15, 2018

Related U.S. Application Data
(62) Division of application No. 15/414,641, filed on Jan. 25, 2017.
Application No. 15/414,641 is a division of application No. 14/048,008, filed on Oct. 7, 2013, now abandoned.

(51) Int. Cl. H01L 21/285; H01L 29/66; H01L 29/45; H01L 29/417; H01L 29/78; H01L 29/08; H01L 27/108; H01L 29/06

(52) U.S. Cl. CPC H01L 21/28525; H01L 29/0657; H01L 29/456; H01L 29/41783; H01L 29/7827; H01L 21/28562; H01L 29/66628; H01L 29/66666; H01L 29/0847; H01L 27/10873; H01L 27/10805; H01L 27/10876; H01L 2924/0002; H01L 27/10823; H01L 29/66568

(57) ABSTRACT

Provided is a method for fabricating a semiconductor device, which includes the following steps. First, a substrate having at least one transistor is provided. A first insulation layer is formed to cover the transistor. The first insulation layer is patterned to form at least one opening, wherein a part of the transistor is exposed by the opening. At last, an epitaxy is formed in the opening to cover the part of the transistor.

This application is a divisional application of the application Ser. No. 15/414,641 field on Jan. 25, 2017, which is a divisional application of the application Ser. No. 14/048,008 field on Oct. 7, 2013, now abandoned, all of which are herein incorporated by reference.

### BACKGROUND

### Technical Field

The present invention relates to a method for manufacturing an electronic device, more particularly, to a method for manufacturing a semiconductor device.

### Description of Related Art

Among semiconductor memory devices, dynamic random access memories (DRAMs) have been widely used. Generally, each cell of a DRAM has a MOS transistor which enables data charges in the storage capacitor to move in data read and write operations.

To be highly integrated, the DRAM should have a capacitor with a sufficient storage capacity and a small unit cell size. In particular, a general approach to reduce a production cost of DRAM is to increase an integration level. To improve an integration density of the DRAM cell, a unit cell size of the DRAM cell needs to be reduced. However, as a semiconductor device is shrunk, characteristics of the transistor of the semiconductor device are degraded by a short channel effect. To solve this issue, on one hand, various structures of planar transistor have been suggested to extend the channel length; however, there are still various concerns to limit it from manufacturing. On the other hand, vertical transistors have been suggested to solve the issue. A vertical transistor has doped source and drain regions, which are formed in a vertical direction, and thus a channel region is vertically formed in a substrate; however, it is difficult to control a body voltage in the vertical transistor having a channel region formed of an undoped silicon (Si) in the related art. Therefore, the vertical transistor has a difficulty in effectively controlling phenomena such as a punch-through effect or a floating body effect. That is, while the vertical transistor is not in operation, a gate induced drain leakage (GIDL) effect is caused due to holes accumulated in a body. Thereby, a current loss in the transistor frequently occurs and charges stored in a capacitor are drained so that a loss of original data is caused. Given the above, improvements in structural design of a semiconductor device with both planar and vertical transistors, and a method for manufacturing thereof are studied aggressively in this field.

### SUMMARY

The present disclosure is to provide a semiconductor device and a method for fabricating the same, which reduce the short channel effect while the dimension of the transistor of the semiconductor device is reduced. Furthermore, the risk of short circuit of adjacent transistors is also avoided.

The present disclosure, in one aspect, relates to a method for fabricating a semiconductor device including the following steps. First, a substrate having at least one transistor is provided. A first insulation layer is formed to cover the transistor. The first insulation layer is patterned to form at least one opening, wherein a part of the transistor is exposed by the opening. At last, an epitaxy is formed in the opening to cover the part of the transistor.

According to one embodiment of the present disclosure, the method further comprises implanting the epitaxy to form a lightly doped epitaxy.

According to one embodiment of the present disclosure, the method further comprises fulfilling the opening with a conductive material.

According to one embodiment of the present disclosure, the first insulation layer is formed by chemical vapor deposition.

According to one embodiment of the present disclosure, before forming the epitaxy, the method further comprises forming a second insulating layer on the first insulation layer, and patterning the second insulation layer to form the opening, wherein the part of the transistor is exposed by the opening of the first and the second insulation layer.

According to one embodiment of the present disclosure, the second insulation layer is formed by chemical vapor deposition.

According to one embodiment of the present disclosure, the transistor is a vertical silicon pillar with a source electrode at the top of the vertical silicon pillar, a drain electrode at the bottom of the vertical silicon pillar, and a gate electrode substantially at the middle of the vertical silicon pillar, the source electrode is the part exposed by the opening and covered by the epitaxy.

According to one embodiment of the present disclosure, the transistor is a vertical silicon pillar with a drain electrode at the top of the vertical silicon pillar, a source electrode at the bottom of the vertical silicon pillar, and a gate electrode substantially at the middle of the vertical silicon pillar, the drain electrode is the part exposed by the opening and covered by the epitaxy.

According to one embodiment of the present disclosure, the transistor has a source, a drain and a gate electrode which are substantially coplanar, at least one of the source and drain electrode is the part exposed by the opening and covered by the epitaxy.

According to one embodiment of the present disclosure, the substrate is silicon and the epitaxy is epitaxial silicon.

The present disclosure, in another aspect, relates to a semiconductor device comprises at least one transistor disposed on a substrate, a first insulation layer, a epitaxy, and a conductive material. The first insulation layer is disposed on the substrate and covers the transistor, wherein the first insulation layer has an opening to expose a part of the transistor. The epitaxy is disposed in the bottom of the opening to covering the part of the transistor. The conductive material is disposed in and fulfills the opening, wherein the conductive material is electrically connected to the part of the transistor through the epitaxy, wherein the boundary of the epitaxy is adjacent to sidewalls of the opening.

According to one embodiment of the present disclosure, the top surface of the epitaxy is substantially flat.

According to one embodiment of the present disclosure, the transistor is a vertical silicon pillar with a drain electrode at the top of the vertical silicon pillar, a source electrode at the bottom of the vertical silicon pillar, and a gate electrode substantially at the middle of the vertical silicon pillar, the drain electrode is the part exposed by the opening and covered by the epitaxy.

According to one embodiment of the present disclosure, the transistor is a vertical silicon pillar with a source electrode at the top of the vertical silicon pillar, a drain electrode at the bottom of the vertical silicon pillar, and a gate electrode substantially at the middle of the vertical silicon pillar, the source electrode is the part exposed by the opening and covered by the epitaxy.

According to one embodiment of the present disclosure, the transistor has a source, a drain and a gate electrode which are substantially coplanar, at least one of the source and drain electrode is the part exposed by the opening and covered by the epitaxy.

According to one embodiment of the present disclosure, the first insulation layer comprises silicon oxide, silicon nitride, or a combination thereof.

According to one embodiment of the present disclosure, the semiconductor device further comprises a second insulation layer disposed on the first insulation layer, wherein the second insulation layer has the opening to expose the part of the transistor.

According to one embodiment of the present disclosure, the second insulation layer comprises silicon oxide, silicon nitride, or a combination thereof.

According to one embodiment of the present disclosure, the conductive material comprises poly silicon, tungsten, titanium, titanium nitride, or a combination thereof.

According to one embodiment of the present disclosure, the substrate is silicon and the epitaxy is doped-epitaxial silicon.

In order to make the aforementioned and other objects, features and advantages of the present disclosure comprehensible, a preferred embodiment accompanied with figures is described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIGS. 1 to 4 are sectional views of fabrication process of a semiconductor device according to the one embodiment of the present disclosure.

FIGS. 5 to 7 are sectional views of fabrication process of a semiconductor device according to the another embodiment of the present disclosure.

FIGS. 8 to 11 are sectional views of fabrication process of a semiconductor device according to the another embodiment of the present disclosure.

FIG. 12 is a sectional view of a semiconductor device according to the another embodiment of the present disclosure.

### DESCRIPTION OF EMBODIMENTS

The present disclosure is described by the following specific embodiments. Those with ordinary skill in the arts can readily understand the other advantages and functions of the present disclosure after reading the disclosure of this specification. The present disclosure can also be implemented with different embodiments. Various details described in this specification can be modified based on different viewpoints and applications without departing from the scope of the present disclosure.

As used herein, the singular forms “a,” “an” and “the” include plural referents unless the context clearly dictates otherwise. Therefore, reference to, for example, a data sequence includes aspects having two or more such sequences, unless the context clearly indicates otherwise.

Reference will now be made in detail to the embodiments of the present disclosure, examples of which are illustrated in the accompanying drawings. Wherever possible, the same reference numbers are used in the drawings and the description to refer to the same or like parts.

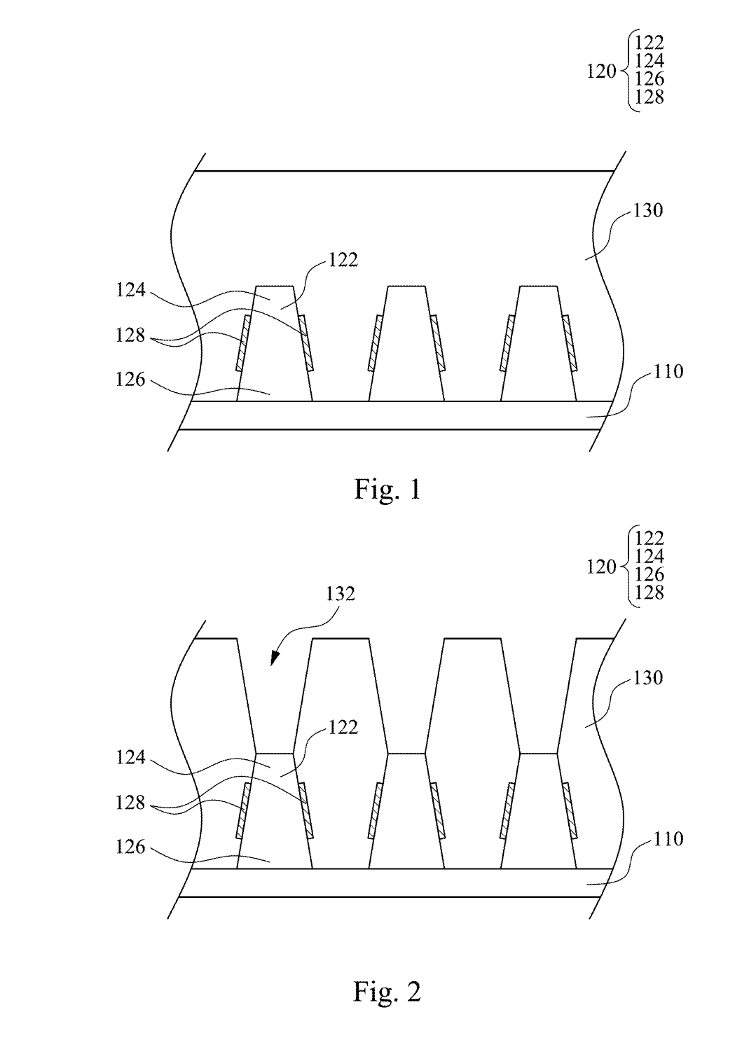

FIGS. 1 to 4 are sectional views illustrating the manufacturing process of a semiconductor device according to some embodiments of the present disclosure. Referring to FIG. 1, a substrate 110 having at least one transistor 120 is provided. The substrate 110 may be a silicon substrate with a plurality of bit line, and each bit line is electrically connected to the transistors 120 arranged in the same line, as the transistors 120 illustrated in FIG. 1. However, the present disclosure is not limited thereto. In some embodiments of the present disclosure, the transistor 120 is a vertical silicon pillar 122. For example, vertical silicon pillars 122 may be arranged periodically and respectively corresponding to different cells of a DRAM. As shown in FIG. 1, in some embodiments of the present disclosure, the vertical silicon pillar 122 has a source electrode 124 at the top of the vertical silicon pillar 122, a drain electrode 126 at the bottom of the vertical silicon pillar 122, and a gate electrode 128 substantially at the middle of the vertical silicon pillar 122. However, the present disclosure is not limited thereto. The relative positions of the source electrode 124 and the drain electrode 126 are exchangeable. In other embodiments of the present disclosure, the vertical silicon pillar 122 has the source electrode 124 at the bottom of the vertical silicon pillar 122, accordingly, the drain electrode 126 at the top of the vertical silicon pillar 122, and the gate electrode 128 substantially at the middle of the vertical silicon pillar. In general, the source electrode 124 and the drain electrode 126 may be formed in the vertical silicon pillar 122 by applying appropriate implant process to the vertical silicon pillar 122. The gate electrode 128 comprises metal or doped semiconductor, and are positioned on both sides of the vertical silicon pillar 122. In FIG. 1, the vertical silicon pillars 122 are vertical transistors 120 on the substrate 110, each vertical silicon pillar 122 has the source electrode 124 and the drain electrode 126 to form a current channel which is perpendicular to the extending direction of the substrate 110, and the gate electrode 128 to control the current flows or not. For example, in DRAM application, the gate electrodes 128 can be word lines which are crossed to the bit lines on the substrate 110.

Referring to FIG. 1, a first insulation layer 130 is formed to cover the transistor 120. The first insulation 130 includes, for example, silicon oxide. In some embodiments of the present disclosure, the first insulation 130 may be formed by chemical vapor deposition.

Referring to FIG. 2, the first insulation layer 130 is patterned to form at least one opening 132 wherein a part of the transistor 120 is exposed by the opening 132. The first insulation 130 may be patterned, for example, by litho-etching process to form the openings 132. The part of the transistor 120 exposed by the opening 132 is the source electrode 124 and/or the drain electrode 126 of the transistor 130. As illustrated in FIG. 2, in some embodiments of the present disclosure, the source electrode 124 is at the top of the vertical silicon pillar 122, and the source electrode 124 is exposed for the following epitaxy formation. In other embodiments of the present disclosure, the drain electrode 126 is at the top of the vertical silicon pillar 122, and the drain electrode 126 is exposed for the following epitaxy formation.

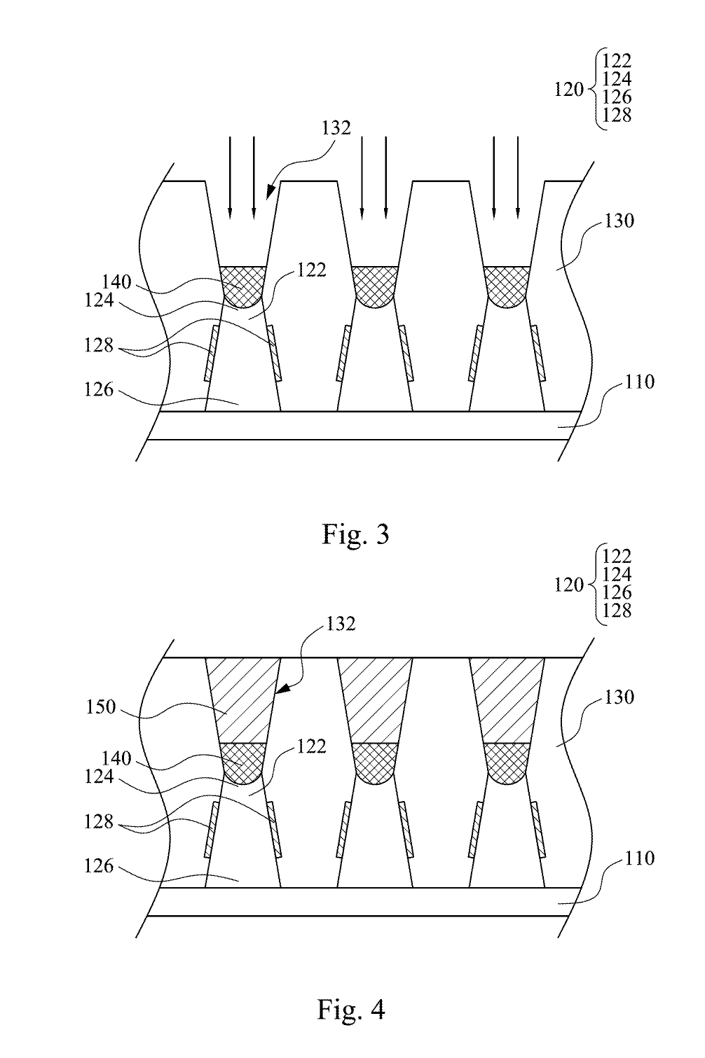

Referring to FIG. 3, an epitaxy 140 is formed in the opening 132 to cover the part of the transistor 130. As illustrated in FIG. 3, in some embodiments of the present disclosure, the source electrode 124 is exposed and the epitaxy 140 is formed on the source electrode 124. In other embodiments of the present disclosure, the drain electrode 126 is exposed and the epitaxy 140 is formed on the source electrode 124. The epitaxy 140 includes epitaxial silicon or other appropriate materials. The epitaxy 140 may be formed by selective CVD process to control the positions of the epitaxy 140 formed. For example, the growth of the epitaxy 140 only starts from the top of the silicon pillars 122 (the source electrode 124 or the drain electrode 126). It should be noticed that, since the epitaxy 140 is formed in the opening 132, the growth of the epitaxy 140 is confined by the opening 132. It eliminates the risk that one epitaxy 140 contacts to another adjacent epitaxy 140, therefore, the interference or short circuit of one transistor 120 and another adjacent transistor 120 is avoided. Besides, the shape of the epitaxy 140 is also confined by the opening 132, therefore, the boundary of the epitaxy 140 is adjacent to sidewalls of the opening. Accordingly, the growth of the epitaxy 140 can be well controlled and the better uniformity between each epitaxy 140 on different transistors 120 can be achieved. In some embodiments of the present disclosure, the epitaxy 140 can be further implanted (as the arrows illustrated in FIG. 3) to form a lightly doped epitaxy to reduce the electrical field between junction and gate, thus the risk of current leakage can be reduced or eliminated. Further, the top surface of the epitaxy 140 may be substantially flat since the growth of the epitaxy 140 is confined by the opening 132 and the growth of the epitaxy 140 can be well controlled. It brings larger process margin for the following process, for example, cleaning and removing the native oxide formed on the epitaxy 140 before fulfilling with a conductive material.

Referring to FIG. 4, in some embodiments of the present disclosure, the opening 132 can be fulfilling with a conductive material 150. The conductive material 150 includes, for example, poly silicon, tungsten, titanium, titanium nitride, or a combination thereof. The conductive material 150 may be formed by, for example, chemical vapor deposition, sputtering or other appropriate thin-film processes. As illustrated in FIG. 4, the conductive material 150 contacts to the epitaxy 140, and the conductive material 150 is also electrically connected to the top of the silicon pillars 122 (the source electrode 124 or the drain electrode 126) via the epitaxy 140. It should be noticed that the epitaxy 140 extends the channel length of the transistor 120. To be more specific, the channel length of the transistor 120 starts from the top of the epitaxy 140, which contacts with the conductive material 150, to the bottom of the silicon pillars 122. As aforementioned, when the dimension of the transistor is reduced, its channel length will also decrease with ease leading to problems such as short channel effect and decrease in turn-on current. The epitaxy 140 in the present disclosure can be the extension of the top of the silicon pillars 122 (as the source or the drain electrode), thus extends the channel length of the transistor 120. Therefore, the issues such as short channel effect and decrease in turn-on current can be improved or eliminated. In addition, it can also reduce the electric field formed between the top of the silicon pillars 122 (as the source or the drain electrode) and the gate electrode 128, so as the gate electrode 128 can be affected less and perform better controllability to the transistor 120.

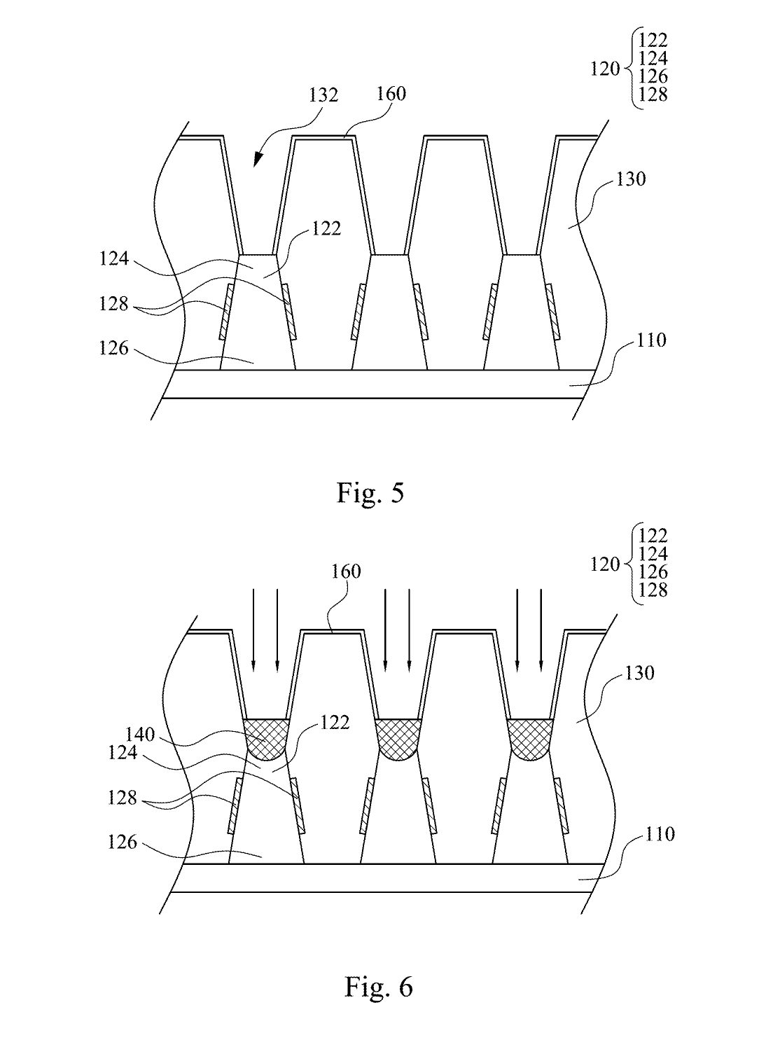

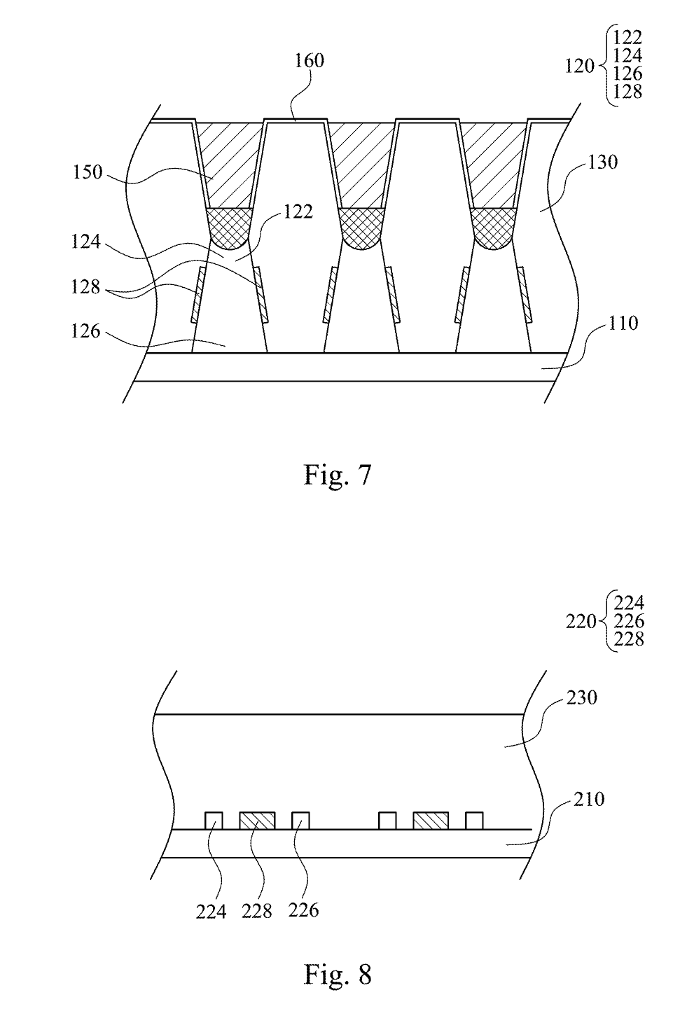

Referring to FIG. 5, in other embodiments of the present disclosure, before forming the epitaxy 140, a second insulating layer 160 is formed on the first insulation layer 160, and the second insulation layer 160 is patterned to form the opening 132, wherein the part of the transistor 120 is exposed by the opening 132 of the first and the second insulation layer. The second insulation 160 may also be composed of a single layer of material or stacked layers of different materials. The second insulation 160 includes, for example, silicon oxide, silicon nitride, or a combination thereof. In some embodiments of the present disclosure, the second insulation 160 may be formed by chemical vapor deposition. The second insulation 160 may be patterned, for example, by litho-etching process to form the openings 132. The part of the transistor 120 exposed by the opening 132 is the source electrode 124 and/or the drain electrode 126 of the transistor 130. The second insulating layer 160 can be a denser film than the first insulating film 130. Therefore, the second insulating layer 160 provides better resistance in the following implanting or cleaning process, thus extends the process margin of these following processes. As illustrated in FIG. 6 and FIG. 7, the epitaxy 140 is formed in the opening 132 to cover the part of the transistor 120 which is exposed by the opening 132 of the first insulation layer 130 and the second insulation layer 160, and the conductive material 150 can also fulfill the opening 132 with a conductive material. The details of FIG. 6 and FIG. 7 are similar to aforementioned embodiments illustrated in FIG. 3 and FIG. 4, and therefore are omitted here.

FIGS. 8 to 10 are sectional views illustrating the manufacturing process of a semiconductor device according to some other embodiments of the present disclosure. Referring to FIG. 8, a substrate 210 having at least one transistor 220 is provided. The substrate 210 may be a silicon substrate with a plurality of bit line, and each bit line is electrically connected to the transistors 220 arranged in the same line, as the transistors 220 illustrated in FIG. 1. The transistor 220 is a planar transistor which has a source electrode 224, a drain electrode 226 and a gate electrode 228 which are substantially coplanar. In general, the source electrode 224 and the drain electrode 226 may be formed by applying appropriate implant process. The gate electrode 228 may comprises metal or doped semiconductor, and are positioned in the middle of the source electrode 224 and the drain electrode 226. In FIG. 8, the transistors 220 are planar transistors 220 on the substrate 210, each transistor 220 has the source electrode 224 and the drain electrode 226 to form a current channel which is horizontal to the extending direction of the substrate 210, and the gate electrode 228 to control the current flows. Referring to FIG. 8, a first insulation layer 230 is formed to cover the transistor 220. The first insulation 230 includes, for example, silicon oxide. In some embodiments of the present disclosure, the first insulation 230 may be formed by chemical vapor deposition.

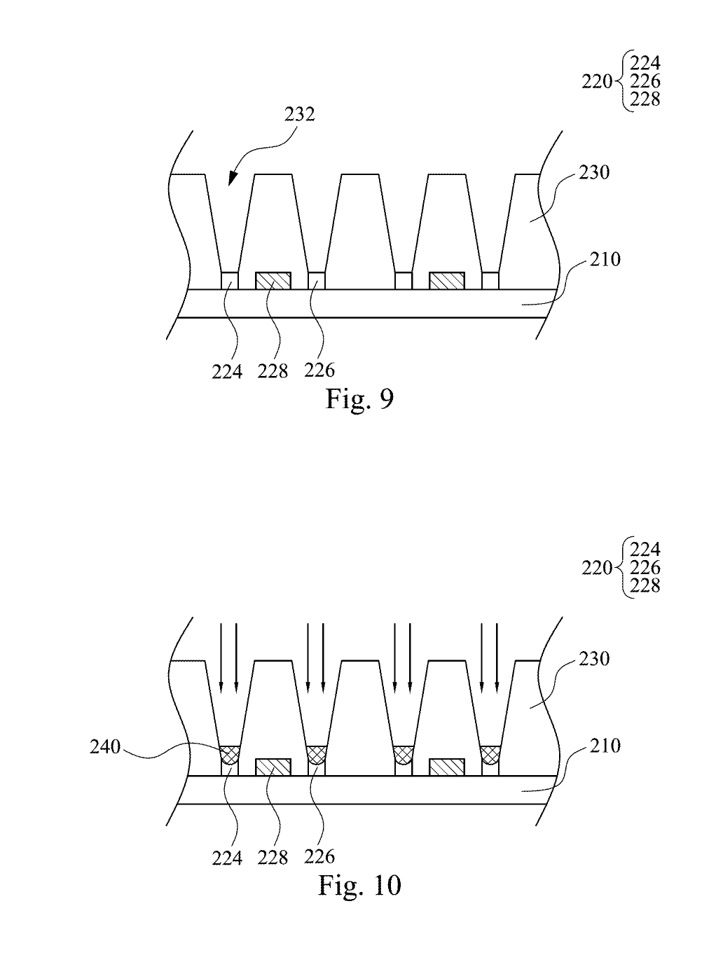

Referring to FIG. 9, the first insulation layer 230 is patterned to form at least one opening 232 wherein a part of the transistor 220 is exposed by the opening 232. The first insulation 230 may be patterned, for example, by litho-etching process to form the openings 232. The part of the transistor 220 exposed by the opening 232 is the source electrode 224 and/or the drain electrode 226 of the transistor 230. As illustrated in FIG. 9, in some embodiments of the present disclosure, both of the source electrode 224 and the drain electrode 226 are exposed for the following epitaxy formation. In some other embodiments of the present disclosure, only one of the source electrode 224 or the drain electrode 226 is exposed for the following epitaxy formation.

Referring to FIG. 10, an epitaxy 240 is formed in the opening 232 to cover the part of the transistor 230. As illustrated in FIG. 10, in some embodiments of the present disclosure, both of the source electrode 224 and the drain electrode 226 are exposed and the epitaxy 240 is formed on both of the source electrode 224 and the drain electrode 226 of the transistor 230. The epitaxy 240 may be formed by selective CVD process to control the positions of the epitaxy 240 formed. It should be noticed that, since the epitaxy 240 is formed in the opening 232, the growth of the epitaxy 240 is confined by the opening 132. It eliminates the risk that one epitaxy 240 contacts to another adjacent epitaxy 240, therefore, the interference or short circuit of one transistor 220 and another adjacent transistor 220 is avoided. Besides, the shape of the epitaxy 240 is also confined by the opening 232, therefore, the boundary of the epitaxy 240 is adjacent to sidewalls of the opening. Accordingly, the growth of the epitaxy 240 can be well controlled and the better uniformity between each epitaxy 240 on different transistors 220 can be achieved. In some embodiments of the present disclosure, the epitaxy 240 can be further implanted (as the arrows illustrated in FIG. 10) to form a lightly doped epitaxy to reduce the electrical field between junction and gate, thus the risk of current leakage can be reduced or eliminated. Further, the top surface of the epitaxy 240 may be substantially flat since the growth of the epitaxy 240 is confined by the opening 232 and the growth of the epitaxy 240 can be controlled well. It brings larger process margin for the following process, for example, cleaning and removing the native oxide formed on the epitaxy 240 before fulfilling with a conductive material.

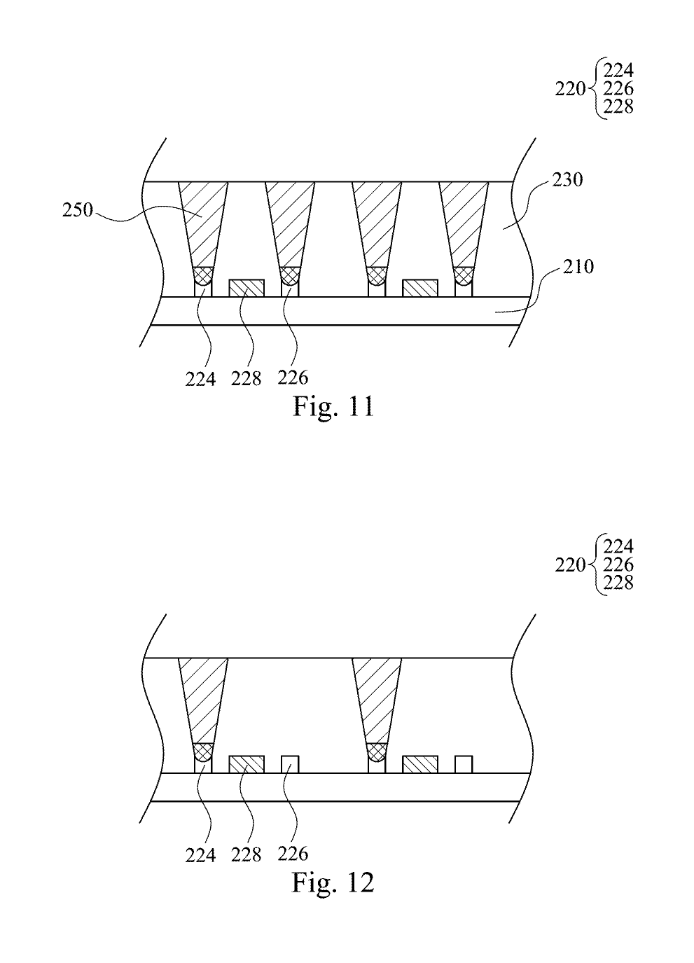

Referring to FIG. 11, in some embodiments of the present disclosure, the opening 232 can be fulfilling with a conductive material 250. The conductive material 250 includes, for example, poly silicon, tungsten, titanium, titanium nitride, or a combination thereof. The conductive material 250 may be formed by, for example, chemical vapor deposition, sputtering or other appropriate thin-film processes. As illustrated in FIG. 11, the conductive material 250 contacts to the epitaxy 240, and the conductive material 250 is also electrically connected to both of the source electrode 224 and the drain electrode 226 of the transistor 220 via the epitaxy 240. Referring to FIG. 12, in some other embodiments of the present disclosure, the conductive material 250 contacts to the epitaxy 240, and the conductive material 250 is only electrically connected to the source electrode 224 of the transistor 220 via the epitaxy 240. However, the present disclosure is not limited thereto. In some other embodiments of the present disclosure, the conductive material 250 is only electrically connected to the source electrode 224 of the transistor 220 via the epitaxy 240. It should be noticed that the epitaxy 240 extends the channel length of the transistor 220. To be more specific, the channel length of the transistor 220 is the distance between the source electrode 224 and the drain electrode 226 which are contacted to the conductive material 250. As aforementioned, when the dimension of the transistor is reduced, its channel length will also decrease with ease leading to problems such as short channel effect and decrease in turn-on current. The epitaxy 240 in the present disclosure can be considered as the extension of the source electrode 224 and the drain electrode 226, thus the channel length of the transistor 220 is extended. Therefore, the issues such as short channel effect and decrease in turn-on current can be improved or eliminated.

In summary, according to the present disclosure, the epitaxy is introduced on at least one of the gate electrode and the drain electrode of the transistor of the semiconductor device. Therefore, the channel length of the transistor can be extended so as to reduce the issues such as short channel while the dimension of the transistor is reduced. Further, since the growth of the epitaxy is confined by the openings which are respectively corresponding to one electrode (the source electrode or the drain electrode) of the transistor. The risk of short circuit by one epitaxy contacts to another adjacent epitaxy is eliminated. Therefore, the interference of one transistor and another adjacent transistor is avoided. Besides, since the shape of the epitaxy is confined by the opening, the growth of the epitaxy can be well controlled and the better uniformity between each epitaxy on different transistors can be achieved.

The present disclosure has been disclosed above in the preferred embodiments, but is not limited to those. It is known to persons skilled in the art that some modifications and innovations may be made without departing from the spirit and scope of the present disclosure. Therefore, the scope of the present disclosure should be defined by the following claims.

What is claimed is:

1. A method for fabricating a semiconductor device, comprising:
providing a substrate having at least one transistor;
forming a first insulation layer to cover the transistor;
patterning the first insulation layer to form at least one opening wherein a part of the transistor is exposed by the opening; and
forming an epitaxy in the opening to cover the part of the transistor.

2. The method of claim 1, further comprising implanting the epitaxy to form a lightly doped epitaxy.

3. The method of claim 2, further comprising fulfilling the opening with a conductive material.

4. The method of claim 1, wherein the first insulation layer is formed by chemical vapor deposition.

5. The method of claim 1, wherein before forming the epitaxy, the method further comprising:
forming a second insulating layer on the first insulation layer; and
patterning the second insulation layer to form the opening, wherein the part of the transistor is exposed by the opening of the first and the second insulation layer.

6. The method of claim 5, wherein the second insulation layer is formed by chemical vapor deposition.

7. The method of claim 1, wherein the transistor is a vertical silicon pillar with a source electrode at the top of the vertical silicon pillar, a drain electrode at the bottom of the vertical silicon pillar, and a gate electrode substantially at the middle of the vertical silicon pillar, wherein the source electrode is the part exposed by the opening and covered by the epitaxy.

8. The method of claim 1, wherein the transistor is a vertical silicon pillar with a drain electrode at the top of the vertical silicon pillar, a source electrode at the bottom of the vertical silicon pillar, and a gate electrode substantially at the middle of the vertical silicon pillar, wherein the drain electrode is the part exposed by the opening and covered by the epitaxy.

9. The method of claim 1, wherein the transistor has a source, a drain and a gate electrode which are substantially coplanar, at least one of the source and drain electrode is the part exposed by the opening and covered by the epitaxy.

10. The method of claim 1, wherein the substrate is silicon and the epitaxy is epitaxial silicon.
